(19) United States
(12) Patent Application Publication
(10) Pub. No.: US 2026/0223327 A1
(43) Pub. Date: Jul. 30, 2026

(54) IMMERSION LIQUID COOLING SYSTEM AND CONTROL METHOD THEREOF, AND DATA CENTER

(71) Applicant: HANGZHOU ALICLOUD FEITIAN FEITIAN INFORMATION TECHNOLOGY CO., LTD., Zhejiang (CN)

(72) Inventors: Han YAN, Hangzhou, Zhejiang (CN); Yiqun GUO, Hangzhou, Zhejiang (CN); Huahua REN, Beijing (CN); Yangfan ZHONG, Shenzhen, Guang Dong (CN)

(21) Appl. No.: 19/147,673

(22) PCT Filed: Jan. 12, 2024
(86) PCT No.: PCT/CN2024/072130

§ 371 Date: Jul. 11, 2025

(30) Foreign Application Priority Data
Jan. 12, 2023 (CN) 202310042053.9

(51) Int. Cl. H05K 7/20; H05K 5/00

(52) U.S. Cl. CPC H05K 7/203; H05K 5/0018; H05K 7/20327; H05K 7/20345; H05K 7/20354; H05K 7/20381; H05K 7/20818; H05K 7/20827

(57) ABSTRACT

The present application provides an immersion liquid cooling system and a control method thereof, and a data center. The immersion liquid cooling system includes a liquid cooling device and a refrigerating device, where the liquid cooling device and the refrigerating device exchange heat through a heat exchanger. The liquid cooling device includes a liquid cooling cabinet and a cooling capacity distribution unit; the cooling capacity distribution unit includes the heat exchanger and a liquid cooling circulation pump, a first medium outlet of the heat exchanger communicates with an inlet-liquid port of the liquid cooling cabinet, a first medium inlet of the heat exchanger communicates with a return-liquid port of the liquid cooling cabinet, the liquid cooling circulation pump is connected in series between the heat exchanger and the liquid cooling cabinet. The refrigerating device includes a refrigerating circulation pump, a condenser, and a throttling apparatus that are sequentially connected in series between a second medium outlet and a second medium inlet of the heat exchanger, and a compressor connected in parallel with the refrigerating circulation pump, where one of the compressor and the refrigerating circulation pump is selected to operate. Therefore, the cooling performance of the immersion liquid cooling system can be improved.

### CROSS-REFERENCE TO RELATED APPLICATIONS

The present application is a National Stage of International Application No. PCT/CN2024/072130, filed on Jan. 12, 2024, which claims priority to Chinese Patent Application No. 202310042053.9, filed on Jan. 12, 2023 to the China National Intellectual Property Administration and entitled “IMMERSION LIQUID COOLING SYSTEM AND CONTROL METHOD THEREOF, AND DATA CENTER”. These applications are incorporated herein by reference in their entireties.

### TECHNICAL FIELD

The present application relates to the field of immersion liquid cooling technology and, in particular, to an immersion liquid cooling system and a control method thereof, and a data center.

### BACKGROUND

With the rapid development of communication and network technology, the size and power density of data centers continue to increase. A data center includes a data processing device, a networking device, and a telecommunication device. These devices mentioned above generate a large amount of heat during operation, causing the temperatures of these devices mentioned above to rise, which in turn affects the power usage effectiveness (Power Usage Effectiveness, abbreviated as PUE) of the data center.

In related arts, in order to decrease a PUE value of the data center, an immersion liquid cooling system is usually used to cool the devices in the data center. However, the immersion liquid cooling system mentioned above has poor cooling performance.

### SUMMARY

Embodiments of the present application provides an immersion liquid cooling system and a control method thereof, and a data center, which can improve the cooling performance of the immersion liquid cooling system.

In a first aspect, an embodiment of the present application provides an immersion liquid cooling system, including: a liquid cooling device and a refrigerating device, where the liquid cooling device and the refrigerating device exchange heat through a heat exchanger; the liquid cooling device includes a liquid cooling cabinet and a cooling capacity distribution unit;

where the cooling capacity distribution unit includes the heat exchanger and a liquid cooling circulation pump, a first medium outlet of the heat exchanger communicates with an inlet-liquid port of the liquid cooling cabinet, a first medium inlet of the heat exchanger communicates with a return-liquid port of the liquid cooling cabinet, the liquid cooling circulation pump is connected in series between the heat exchanger and the liquid cooling cabinet; the refrigerating device includes a refrigerating circulation pump, a condenser, and a throttling apparatus that are sequentially connected in series between a second medium outlet and a second medium inlet of the heat exchanger, and a compressor connected in parallel with the refrigerating circulation pump, where one of the compressor and the refrigerating circulation pump is selected to operate.

In a possible implementation, the liquid cooling device further includes a housing and an electronic control apparatus; the liquid cooling cabinet, the cooling capacity distribution unit, and the electronic control apparatus are all arranged in the housing; the electronic control apparatus is configured to control the cooling capacity distribution unit.

In a possible implementation, an inlet-liquid temperature sensor and a return-liquid temperature sensor are also provided in the housing, the inlet-liquid temperature sensor is arranged close to the inlet-liquid port of the liquid cooling cabinet, and the return-liquid temperature sensor is arranged close to the return-liquid port of the liquid cooling cabinet; the inlet-liquid temperature sensor and the return-liquid temperature sensor are both electrically connected to the electronic control apparatus.

In a possible implementation, a surface of the housing is provided with a touch screen, and the touch screen is configured to control and display a state of the liquid cooling device.

In a possible implementation, the refrigerating device further includes a spraying apparatus, the spraying apparatus is arranged close to the condenser, and the spraying apparatus is configured to spray coolant to the condenser.

In a possible implementation, the liquid cooling device includes a first medium, the first medium flows in circulation in the liquid cooling cabinet and the cooling capacity distribution unit, and the first medium is electronic fluorine liquid.

In a possible implementation, the refrigerating device includes a second medium, the second medium flows in circulation in the heat exchanger and the refrigerating device, and the second medium is Freon.

In a possible implementation, the condenser includes a condensing tube, a heat dissipation fin, and a fan; the heat dissipation fin is arranged on an outer surface of the condensing tube, the fan is arranged close to the condensing tube, and the fan is configured to drive air around the condensing tube to flow.

In a second aspect, an embodiment of the present application provides an immersion liquid cooling system, including: a liquid cooling device and two refrigerating devices, where the liquid cooling device and the two refrigerating devices exchange heat through a heat exchanger; the liquid cooling device includes a liquid cooling cabinet and two cooling capacity distribution units; where the cooling capacity distribution unit includes the heat exchanger and a liquid cooling circulation pump, a first medium outlet of the heat exchanger communicates with an inlet-liquid port of the liquid cooling cabinet, a first medium inlet of the heat exchanger communicates with a return-liquid port of the liquid cooling cabinet, the liquid cooling circulation pump is connected in series between the heat exchanger and the liquid cooling cabinet; the two refrigerating devices respectively correspond to the two cooling capacity distribution units; the refrigerating device includes a refrigerating circulation pump, a condenser, and a throttling apparatus that are sequentially connected in series between a second medium outlet and a second medium inlet of the heat exchanger, and a compressor connected in parallel with the refrigerating circulation pump, where one of the compressor and the refrigerating circulation pump is selected to operate.

In a possible implementation, the liquid cooling device further includes a housing and two electronic control apparatuses; the liquid cooling cabinet, the two cooling capacity distribution units, and the two electronic control apparatuses are all arranged in the housing; the two electronic control apparatuses are respectively configured to control the two cooling capacity distribution units.

In a possible implementation, an inlet-liquid temperature sensor and a return-liquid temperature sensor are also provided in the housing, the inlet-liquid temperature sensor is arranged close to the inlet-liquid port of the liquid cooling cabinet, and the return-liquid temperature sensor is arranged close to the return-liquid port of the liquid cooling cabinet; the inlet-liquid temperature sensor and the return-liquid temperature sensor are both electrically connected to the electronic control apparatus.

In a possible implementation, a surface of the housing is provided with a touch screen, and the touch screen is configured to control and display a state of the liquid cooling device.

In a possible implementation, the refrigerating device further includes a spraying apparatus, the spraying apparatus is arranged close to the condenser, and the spraying apparatus is configured to spray coolant to the condenser.

In a possible implementation, the liquid cooling device includes a first medium, the first medium flows in circulation in the liquid cooling cabinet and the cooling capacity distribution unit, and the first medium is electronic fluorine liquid.

In a possible implementation, the refrigerating device includes a second medium, and the second medium flows in circulation in the heat exchanger and the refrigerating device; the second medium is Freon.

In a possible implementation, the condenser includes a condensing tube, a heat dissipation fin, and a fan; the heat dissipation fin is arranged on an outer surface of the condensing tube, the fan is arranged close to the condensing tube, and the fan is configured to drive air around the condensing tube to flow.

In a possible implementation, the two cooling capacity distribution units are arranged on a same side of the liquid cooling cabinet; or, the two cooling capacity distribution units are arranged respectively on two opposite sides of the liquid cooling cabinet.

In a possible implementation, the two refrigerating devices are integrated together.

In a third aspect, an embodiment of the present application provides a data center, including a server room and the immersion liquid cooling system described according to any above item; where the liquid cooling device of the immersion liquid cooling system is arranged inside the server room, the refrigerating device of the immersion liquid cooling system is arranged outside the server room, and the liquid cooling device and the refrigerating device are connected via a pipeline passing through a wall of the server room.

In a fourth aspect, an embodiment of the present application provides a control method of an immersion liquid cooling system, applied to the immersion liquid cooling system described according to the above second aspect; where the method includes:
starting up the immersion liquid cooling system, where the two refrigerating devices both operate in a pump mode;
acquiring a return-liquid temperature and an inlet-liquid temperature of the liquid cooling cabinet;
determining whether the return-liquid temperature is greater than a preset return-liquid temperature;
if not, controlling an operation state of the immersion liquid cooling system according to the inlet-liquid temperature;
where the operation state of the immersion liquid cooling system includes: the two refrigerating devices both operating in a compressor mode; the two refrigerating devices both operating in the pump mode; or, one of the two refrigerating devices operating in the compressor mode and the other one of the two refrigerating devices operating in the pump mode.

In a possible implementation, after the determining whether the return-liquid temperature is greater than the preset return-liquid temperature, the control method of the immersion liquid cooling system further includes:
if so,
determining whether the inlet-liquid temperature is greater than a preset inlet-liquid temperature;
if not, controlling the operation state of the immersion liquid cooling system according to the return-liquid temperature;
if so, controlling the operation state of the immersion liquid cooling system according to the return-liquid temperature and the inlet-liquid temperature.

In a possible implementation, the controlling the operation state of the immersion liquid cooling system according to the inlet-liquid temperature includes:
determining whether the inlet-liquid temperature is greater than the preset inlet-liquid temperature;
if not, decreasing a rotating speed of at least one of a fan of the condenser, the refrigerating circulation pump, or the liquid cooling circulation pump, to make a total power of the fan of the condenser, the refrigerating circulation pump, and the liquid cooling circulation pump to be a preset minimum power value;
acquiring and determining a first difference value of the inlet-liquid temperature and the preset inlet-liquid temperature;
when the first difference value is greater than or equal to a first preset difference value, stopping decreasing the rotating speed;
when the first difference value is greater than or equal to a second preset difference value, controlling the fan of the condenser to stop operating, controlling the refrigerating circulation pump to operate at a preset minimum rotating speed, and controlling the liquid cooling circulation pump to operate at a preset minimum rotating speed;
where the first preset difference value is smaller than the second preset difference value.

In a possible implementation, the controlling the operation state of the immersion liquid cooling system according to the inlet-liquid temperature includes:
determining whether the inlet-liquid temperature is greater than the preset inlet-liquid temperature;
if so, acquiring and determining a second difference value of the inlet-liquid temperature and the preset inlet-liquid temperature;
when the second difference value is greater than or equal to a third preset difference value, increasing the rotating speed of the fan of the condenser, and/or, increasing the rotating speed of the refrigerating circulation pump;
when the second difference value is greater than or equal to a fourth preset difference value, controlling at least one of the two refrigerating devices to operate in the compressor mode;
when the second difference value is greater than or equal to a fifth preset difference value, controlling the two refrigerating devices both to operate in the compressor mode, and loading compressors of the two refrigerating devices both to more than 50%;
where the third preset difference value, the fourth preset difference value, and the fifth preset difference value increases sequentially.

In a possible implementation, the when the second difference value is greater than or equal to a fourth preset difference value, controlling at least one of the two refrigerating devices to operate in the compressor mode includes:
controlling one of the two refrigerating devices to switch to the compressor mode;
when the compressor of the one of the two refrigerating devices is loaded to 50%, determining whether the second difference value is smaller than or equal to the third preset difference value;
if not, controlling the other one of the two refrigerating devices to switch to the compressor mode;
when the compressor of the other one of the two refrigerating devices is loaded to 50%, determining whether the second difference value is smaller than or equal to the third preset difference value;
if not, controlling the compressors of the two refrigerating devices both to continue loading.

In a possible implementation, the when the second difference value is greater than or equal to a fifth preset difference value, controlling the two refrigerating devices both to operate in the compressor mode, and loading the compressors of the two refrigerating devices both to more than 50% includes:
controlling the compressors of the two refrigerating devices both to be loaded to 60%;
determining whether the second difference value is 0;
if so, maintaining the compressors of the two refrigerating devices both to operate with a load of 60%;
if not, determining whether the second difference value is smaller than or equal to the third preset difference value;
if so, controlling the compressors of the two refrigerating devices both to continue loading at a first rate;
if not, controlling the compressors of the two refrigerating devices both to continue loading at a second rate;
where the first rate is smaller than the second rate.

In a possible implementation, the controlling the operation state of the immersion liquid cooling system according to the return-liquid temperature includes:
acquiring and determining a third difference value of the return-liquid temperature and the preset return-liquid temperature;
when the third difference value is greater than or equal to a sixth preset difference value, increasing a rotating speed of at least one of a fan of the condenser, the refrigerating circulation pump, or the liquid cooling circulation pump;
when the third difference value is greater than or equal to a seventh preset difference value, controlling the two refrigerating devices both to operate in the compressor mode;
where the sixth preset difference value is smaller than the seventh difference value.

In a possible implementation, the controlling the operation state of the immersion liquid cooling system according to the return-liquid temperature and the inlet-liquid temperature includes:
acquiring and determining a second difference value of the inlet-liquid temperature and the preset inlet-liquid temperature;
acquiring and determining a third difference value of the return-liquid temperature and the preset return-liquid temperature;
when the second difference value is smaller than or equal to a third preset difference value and the third difference value is smaller than or equal to a sixth preset difference value, controlling the two refrigerating devices both to operate in the pump mode;
when the second difference value is smaller than or equal to the third preset difference value and the third difference value is greater than the sixth preset difference value, controlling the two refrigerating devices both to operate in the compressor mode.

In a possible implementation, the method further includes:
acquiring and determining a condensing temperature of the condenser;
when the condensing temperature is greater than a preset condensing temperature, controlling a spraying apparatus to spray coolant to the condenser;
when the condensing temperature is smaller than the preset condensing temperature, and a difference value of the condensing temperature and the preset condensing temperature is greater than or equal to an eighth preset difference value, controlling the spraying apparatus to stop spraying.

In a possible implementation, the method further includes:
acquiring and determining an outdoor environment temperature, and a difference value of an outdoor dry bulb temperature and an outdoor wet bulb temperature;
when the outdoor environment temperature is greater than a preset temperature, and the difference value of the outdoor dry bulb temperature and the outdoor wet bulb temperature is greater than a ninth preset difference value, controlling a spraying apparatus to spray coolant to the condenser;
when the outdoor environment temperature is smaller than the preset temperature, controlling the spraying apparatus to stop spraying.

In a fifth aspect, an embodiment of the present application provides a control device, including: a processor and a memory; where the memory stores computer executable instructions; the processor executes the computer executable instructions stored in the memory, to implement the control method of the immersion liquid cooling system described according to the above fourth aspect.

In a sixth aspect, an embodiment of the present application provides a computer readable storage medium, where the computer readable storage medium stores computer executable instructions; when the computer executable instructions are executed by a processor, the control method of the immersion liquid cooling system described according to the above fourth aspect is implemented.

In a seventh aspect, an embodiment of the present application provides a program product, including a computer program; when the computer program is executed by a processor, the control method of the immersion liquid cooling system described according to the above fourth aspect is implemented.

The immersion liquid cooling system provided in the embodiments of the present application, by means of setting the refrigerating device and the liquid cooling device to be connected and exchange heat through the heat exchanger, enables the refrigerating device to provide cooling capacity to the liquid cooling device, to ensure that a cooling temperature of the liquid cooling device meets the requirement. By means of setting the refrigerating device to include the compressor and the refrigerating circulation pump that are connected to each other in parallel, the refrigerating device can switch between the compressor operation mode and the refrigerating circulation pump operation mode. Cooling capability of the refrigerating device in the compressor operation mode is stronger than that in the refrigerating circulation pump operation mode, and therefore, the refrigerating device can switch to the compressor operation mode when the liquid cooling device of the immersion liquid cooling system needs to provide a relatively low cooling temperature; the refrigerating device can switch to the refrigerating circulation pump operation mode when the liquid cooling device of the immersion liquid cooling system needs to provide a relatively high cooling temperature. Furthermore, the immersion liquid cooling system can flexibly adjust the cooling temperature provided by the liquid cooling device to adapt to devices to be cooled with different cooling temperature requirements. This not only expands the application scope of the immersion liquid cooling system, but also improves the cooling efficiency and the cooling performance of the immersion liquid cooling system.

The control method of the immersion liquid cooling system provided in the embodiments of the present application, by means of setting the refrigerating device to switch between the compressor operation mode and the refrigerating circulation pump operation mode according to an operating temperature of the liquid cooling device, enables the immersion liquid cooling system to flexibly adjust the cooling temperature provided by the liquid cooling device, thereby adapting to devices to be cooled with different cooling temperature requirements. Thus, this not only expands the application scope of the immersion liquid cooling system, but also improves the cooling efficiency and the cooling performance of the immersion liquid cooling system.

The data center provided in the embodiments of the present application includes the immersion liquid cooling system mentioned above, and therefore the effects of the immersion liquid cooling system are also present in the data center of the embodiments of the present application, which will not be repeated here.

In addition to the above-described technical problems solved by the embodiments of the present application, the technical features that constitute the technical solution(s), and the beneficial effects brought by these technical features of the technical solution(s), other technical problems that can be solved by the immersion liquid cooling system and the control method thereof provided by the embodiments of the present application as well as the data center, other technical features included in the technical solution(s), and the beneficial effects brought by these technical features will be further explained in detail in the description of the embodiments.

### BRIEF DESCRIPTION OF DRAWINGS

In order to illustrate the technical solutions of embodiments of the present application or the prior art more clearly, the drawings that need to be used in the description of the embodiments of the present application or in the description of the prior arts will be briefly introduced in the following. Obviously, the drawings in the following description are intended for some embodiments of the present application. For those of ordinary skill in the art, other drawings can be obtained according to these drawings without any creative effort.

FIG. 1 is a schematic diagram of constituent structure of an immersion liquid cooling system provided in an embodiment of the present application.

FIG. 2 is a schematic diagram of connecting structure of an immersion liquid cooling system provided in an embodiment of the present application.

FIG. 3 is a schematic diagram of constituent structure of another immersion liquid cooling system provided in an embodiment of the present application.

FIG. 4 is a schematic diagram of connecting structure of another immersion liquid cooling system provided in an embodiment of the present application.

FIG. 5 is a first flowchart of a control method of an immersion liquid cooling system provided in an embodiment of the present application.

FIG. 6 is a second flowchart of a control method of an immersion liquid cooling system provided in an embodiment of the present application.

FIG. 7 is a third flowchart of a control method of an immersion liquid cooling system provided in an embodiment of the present application.

FIG. 8 is a fourth flowchart of a control method of an immersion liquid cooling system provided in an embodiment of the present application.

FIG. 9 is a fifth flowchart of a control method of an immersion liquid cooling system provided in an embodiment of the present application.

FIG. 10 is a sixth flowchart of a control method of an immersion liquid cooling system provided in an embodiment of the present application.

FIG. 11 is a schematic diagram of a control apparatus of an immersion liquid cooling system provided in an embodiment of the present application.

FIG. 12 is a schematic diagram of a control device of an immersion liquid cooling system provided in an embodiment of the present application.

Reference signs:
100—Liquid cooling device; 110—Housing; 120—Liquid cooling cabinet; 130—Cooling capacity distribution unit; 131—Heat exchanger; 132—Liquid cooling circulation pump; 133—Liquid trapper; 151—First regulating valve; 152—Second regulating valve; 153—Third regulating valve; 154—Fourth regulating valve;
200—Refrigerating device; 210—Mounting bracket; 221—Refrigerating circulation pump; 222—Compressor; 230—Condenser; 240—Throttling apparatus; 250—Spraying apparatus; 261—Fifth regulating valve; 262—Sixth regulating valve; 263—Seventh regulating valve; 264—Eighth regulating valve; 265—Ninth regulating valve;
300—Pipeline;
10—Apparatus; 11—Acquiring module; 12—Determining module; 13—Controlling module;
20—Device; 21—Processor; 22—Memory; 23—Communication bus

### DESCRIPTION OF EMBODIMENTS

In order to make the purpose, characteristics, and advantages of the embodiments of the present application clearer and more understandable, the following will provide a clear and comprehensive description of the technical solution in the embodiments of the present application in conjunction with the accompanying drawings of the embodiments of the present application. Obviously, the described embodiments are a part of the embodiments of the present application, not all of them. Based on the embodiments of the present application, all other embodiments obtained by those of ordinary skill in the art without any creative effort are within the protection scope of the present application.

As described in the BACKGROUND, an immersion liquid cooling system in related arts has the problem of poor cooling performance. The main reason for this problem is that the immersion liquid cooling system usually includes a liquid cooling device and a refrigerating device. The liquid cooling device and the refrigerating device exchange heat through a heat exchanger. The liquid cooling device contains a first medium and a heating element immersed in the first medium. The first medium absorbs heat from the heating element and flows through the heat exchanger to exchange heat with the refrigerating device, then returns to the liquid cooling device to continue cooling the heating element. There is a second medium flowing in circulation in the refrigerating device, and the second medium can take away the heat of the first medium when flowing through the heat exchanger. However, the single operation mode of the refrigerating device results in the inability to freely adjust the liquid cooling temperature of the immersion liquid cooling system, leading to the poor cooling performance of the immersion liquid cooling system.

The liquid cooling cabinet and the heat exchanger are connected to each other. The liquid cooling cabinet contains a first medium and a heating element immersed in the first medium. The first medium absorbs the heat from the heating element and then flows into the heat exchanger to exchange heat with air for cooling. The cooled first medium flows back to the liquid cooling device to continue cooling the heating element. However, the first medium flowing through the heat exchange device mainly relies on heat exchange with air, which is difficult to restore to the ideal state, resulting in poor cooling performance of the immersion liquid cooling system.

In view of this, the embodiments of the present application provide an immersion liquid cooling system and a control method thereof. The immersion liquid cooling system, by means of setting the refrigerating device and the liquid cooling device to be connected and exchange heat through the heat exchanger, enables the refrigerating device to provide cooling capacity to the liquid cooling device, to ensure that a cooling temperature of the liquid cooling device meets the requirement. By means of setting the refrigerating device to include the compressor and the refrigerating circulation pump that are connected to each other in parallel, the refrigerating device is enabled to switch between the compressor operation mode and the refrigerating circulation pump operation mode. Cooling capability of the refrigerating device in the compressor operation mode is stronger than that in the refrigerating circulation pump, and therefore, the refrigerating device can switch to the compressor operation mode when the liquid cooling device of the immersion liquid cooling system needs to provide a relatively low cooling temperature; the refrigerating device can switch to the refrigerating circulation pump operation mode when the liquid cooling device of the immersion liquid cooling system needs to provide a relatively high cooling temperature. Furthermore, the immersion liquid cooling system can flexibly adjust the cooling temperature provided by the liquid cooling device to adapt to devices to be cooled with different cooling temperature requirements. This not only expands the application scope of the immersion liquid cooling system, but also improves the cooling efficiency and the cooling performance of the immersion liquid cooling system.

The control method of the immersion liquid cooling system, by means of setting the refrigerating device to switch between the compressor operation mode and the refrigerating circulation pump operation mode according to an operating temperature of the liquid cooling device, enables the immersion liquid cooling system to flexibly adjust the cooling temperature provided by the liquid cooling device, to adapt to devices to be cooled with different cooling temperature requirements. Thus, this not only expands the application scope of the immersion liquid cooling system, but also improves the cooling efficiency and the cooling performance of the immersion liquid cooling system.

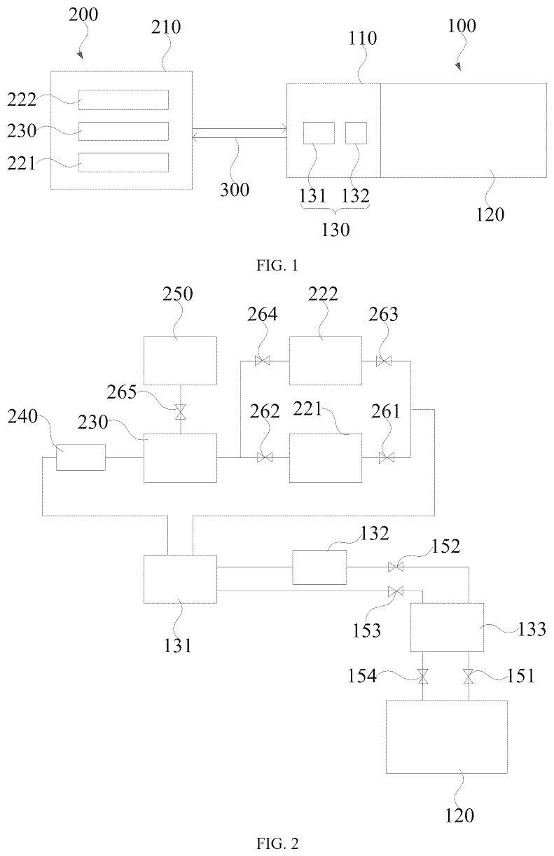

Referring to FIG. 1 and FIG. 2, an embodiment of the present application provides an immersion liquid cooling system. The immersion liquid cooling system includes a liquid cooling device 100 and a refrigerating device 200, where the liquid cooling device 100 and the refrigerating device 200 exchange heat through a heat exchanger 131.

The liquid cooling device 100 may include a liquid cooling cabinet 120 and a cooling capacity distribution unit, the liquid cooling device 100 may further include a housing 110 and a first electronic control apparatus, the housing 110 including, but not limited to, a metal housing 110 or a plastic housing 110. The liquid cooling cabinet 120, the cooling capacity distribution unit, and the first electronic control apparatus can all be arranged in the housing 110. The housing 110 can integrate the liquid cooling cabinet 120, the cooling capacity distribution unit, and the first electronic control apparatus together, and the control logic debugging of the first electronic control apparatus can be completed before the liquid cooling equipment 100 leaves the factory, thereby improving the on-site installation efficiency of the liquid cooling device 100 and saving the on-site installation time of the liquid cooling device 100.

The liquid cooling cabinet 120 may be a liquid cooling cabinet 120 with a 33 U specification. For example, a 33 U liquid cooling cabinet 120 can accommodate thirty 1 U servers and three 1 U switches; or, the liquid cooled cabinet 120 with the 33 U specification can accommodate ten 3 U servers and three 1 U switches. “U” is a unit that represents an external dimension of a server and is an abbreviation for Unit. The specific size represented by 1 U is determined by the Electronic Industries Association (Electronic Industries Association, EIA) in the United States, with 1 U=1.75 inches=44.45 millimeters=4.445 centimeters. Those skilled in the art can understand that in the actual manufacturing process, there may be allowable deviations in the actual size of “U”.

The cooling capacity distribution unit 130 may include the heat exchanger 131 and a liquid cooling circulation pump 132. For example, the heat exchanger 131 may be a plate heat exchanger 131. The heat exchanger 131 may include a first medium inlet, a first medium outlet, a second medium inlet and a second medium outlet, the first medium inlet communicates with the first medium outlet, and the second medium inlet communicates with the second medium outlet. Specifically, the first medium outlet can communicate with an inlet-liquid port of the liquid cooling cabinet 120, and the first medium inlet can communicate with a return-liquid port of the liquid cooling cabinet 120; the refrigerating device 200 can be connected in series between the second medium outlet and the second medium inlet.

The liquid cooling device 100 may include a first medium, the first medium flows in circulation in the liquid cooling cabinet 120 and the cooling capacity distribution unit 130, and the first medium may be electronic fluorine liquid. The refrigerating device 200 may include a second medium, the second medium flows in circulation in the heat exchanger 131 and the refrigerating device 200, and the second medium may be Freon. The first medium flowing into the heat exchanger 131 through the first medium inlet and the second medium flowing into the heat exchanger 131 through the second medium inlet can exchange heat with each other, so that the first medium can carry the heat from the liquid cooling cabinet 120 to the heat exchanger 131 and transfer the heat to the second medium.

The liquid cooling circulation pump 132 may be connected in series between the heat exchanger 131 and the liquid cooling cabinet 120. For example, the liquid cooling circulation pump 132 can be connected in series between the first medium outlet of the heat exchanger 131 and the inlet-liquid port of the liquid cooling cabinet 120; or, the liquid cooling circulation pump 132 can be connected in series between the first medium inlet of the heat exchanger 131 and the return-liquid port of the liquid cooling cabinet 120. The liquid cooling circulation pump 132 is configured to drive the first medium to flow in circulation between the heat exchanger 131 and the liquid cooling cabinet 120.

The first electronic control apparatus may be configured to control the cooling capacity distribution unit 130. The first electronic control apparatus can be electrically connected to the liquid cooling circulation pump 132, in order to control a rotating speed of the liquid cooling circulation pump 132, to achieve the purpose of controlling the cooling capacity distribution unit 130 and further achieve the purpose of controlling the immersion liquid cooling system. For example, the first electronic control apparatus may be a programmable logic controller (Programmable Logic Controller, abbreviated as PLC).

In the housing 110, a liquid trapper 133 may also be provided, and the liquid trapper 133 may be connected in series between the heat exchanger 131 and the liquid cooling cabinet 120. For example, the liquid trapper 133 includes a first inlet, a first outlet, a second inlet and a second outlet, the first inlet communicates with the second outlet, and the second inlet communicates with the second outlet. Specifically, the first medium outlet of the heat exchanger 131 can communicates with the first inlet, and the first outlet can communicates with the inlet-liquid port of the liquid cooling cabinet 120, the first medium inlet of the heat exchanger 131 can communicates with the second outlet, and the second inlet can communicates with the return-liquid port of the liquid cooling cabinet 120. The liquid trapper 133 is used for centralized recovery of the first medium before the first medium enters the liquid cooling cabinet 120 and after it leaves the liquid cooling cabinet 120. At this time, the liquid cooling circulation pump 132 can be connected in series between the first medium outlet of the heat exchanger 131 and the first inlet of the liquid trapper 133; or, the liquid cooling circulation pump 132 can be connected in series between the first medium inlet of the heat exchanger 131 and the second outlet of the liquid trapper 133.

In the housing 110, an inlet-liquid temperature sensor and a return-liquid temperature sensor may be further provided. The inlet-liquid temperature sensor may be arranged close to the inlet-liquid port of the liquid cooling cabinet 120, to enable the inlet-liquid temperature sensor to detect an inlet-liquid temperature of the liquid cooling cabinet 120. The return-liquid temperature sensor may be arranged close to the return-liquid port of the liquid cooling cabinet 120, to enable the return-liquid temperature sensor to detect a return-liquid temperature of the liquid cooling cabinet 120. The inlet-liquid temperature sensor and the return-liquid temperature sensor can both be electrically connected to the first electronic control apparatus to transmit the inlet-liquid temperature and the return-liquid temperature of the liquid cooling cabinet 120 to the first electronic control apparatus, in order that the first electronic control apparatus controls the cooling capacity distribution unit 130 according to the inlet-liquid temperature and the return-liquid temperature and further controls the immersion liquid cooling system.

The liquid cooling device 100 may further include a first regulating valve 151, a second regulating valve 152, a third regulating valve 153 and a fourth regulating valve 154. Specifically, the first regulating valve 151 may be arranged at a first inlet end of the liquid trapper 133, the second regulating valve 152 may be arranged at a first outlet end of the liquid trapper 133, the third regulating valve 153 may be arranged at a second inlet end of the liquid trapper 133, the fourth regulating valve 154 may be arranged at a second outlet end of the liquid trapper 133. The first regulating valve 151, the second regulating valve 152, the third regulating valve 153 and the fourth regulating valve 154 can all be electrically connected to the first electronic control apparatus to enable the first electronic control apparatus to achieve the purpose of controlling the cooling capacity distribution unit 130 by controlling the first regulating valve 151, the second regulating valve 152, the third regulating valve 153 and the fourth regulating valve 154.

A surface of the housing 110 may be provided with a touch screen, and the touch screen can be configured to control and display a state of the liquid cooling device 100. The touch screen may be electrically connected to the first electronic control apparatus to enable an operator to quickly acquire a status parameter of the liquid cooling device 100 through the touch screen and control a status parameter of the liquid cooling device 100 through the touch screen. For example, the touch screen may be a 10-inch touch screen, and the touch screen may be located on a top surface of the housing 110. Of course, the shape, size, and arranged location of the touch screen can also be set according to actual needs, and there are no specific restrictions here.

The refrigerating device 200 may include a refrigerating circulation pump 221, a condenser 230, and a throttling apparatus 240 that are sequentially connected in series between a second medium outlet and a second medium inlet of the heat exchanger 131, and a compressor 222 connected in parallel with the refrigerating circulation pump 221, where one of the compressor 222 and the refrigerating circulation pump 221 is selected to operate. For example, the condenser 230 may include a condensing tube, a heat dissipation fin, and a fan; the heat dissipation fin is arranged on an outer surface of the condensing tube, the fan is arranged close to the condensing tube, and the fan is configured to drive air around the condensing tube to flow, to improve the condensing performance of the condenser 230. The throttling apparatus 240 may be a throttling valve.

The refrigerating device 200 may further include a second electronic control apparatus, and the second electronic control apparatus can be configured to control the refrigerating device 200. The second electronic control apparatus can be electrically connected to the refrigerating circulation pump 221, the compressor 222 and the fan of the condenser 230, in order to control a rotating speed of the refrigerating circulation pump 221, a load of the compressor 222 and a rotating speed of the fan of the condenser 230. The second electronic control apparatus may be communicatively connected to the first electronic control apparatus, whereby the second electronic control apparatus and the first electronic control apparatus cooperate with each other to control the immersion liquid cooling system. For example, the second electronic control apparatus may be a programmable logic controller (Programmable

Logic Controller, abbreviated as PLC).

The refrigerating device 200 may further include a spraying apparatus 250, the spraying apparatus 250 is arranged close to the condenser 230, and the spraying apparatus 250 is configured to spray coolant to the condenser 230. For example, the spraying apparatus 250 may include a booster pump and multiple nozzles connected to the booster pump. The multiple nozzles may be arranged around the condenser 230, facing the condenser 230, and the multiple nozzles may spray the coolant onto the condenser 230. The coolant may be water or other liquids, thereby decreasing a temperature of the condenser 230 and improving the condensing performance of the condenser 230.

The refrigerating device 200 may further include a fifth regulating valve 261, a sixth regulating valve 262, a seventh regulating valve 263, an eighth regulating valve 264 and a ninth regulating valve 265. Specifically, the fifth regulating valve 261 and the sixth regulating valve 262 may be respectively arranged at an inlet end and an outlet end of the refrigerating circulation pump 221, the seventh regulating valve 263 and the eighth regulating valve 264 may be respectively arranged at an inlet end and an outlet end of the compressor 222, and the ninth regulating valve 265 may be arranged on the spraying apparatus 250 and configured to control the opening and closing of the spraying apparatus 250. The fifth regulating valve 261, the sixth regulating valve 262, the seventh regulating valve 263, the eighth regulating valve 264 and the ninth regulating valve 265 can all be electrically connected to the second electronic control apparatus to enable the second electronic control apparatus to achieve the purpose of controlling the refrigerating device 200 by controlling the fifth regulating valve 261, the sixth regulating valve 262, the seventh regulating valve 263, the eighth regulating valve 264 and the ninth regulating valve 265.

The refrigerating device 200 may further include a mounting bracket 210; the refrigerating circulation pump 221, the condenser 230, the throttling apparatus 240, the compressor 222 and the spraying apparatus 250 may all be installed on the mounting bracket 210 to integrate the refrigerating device 200 together, so that the on-site installation efficiency of the refrigerating device 200 can be improved and the on-site installation time of the refrigerating device 200 can be saved.

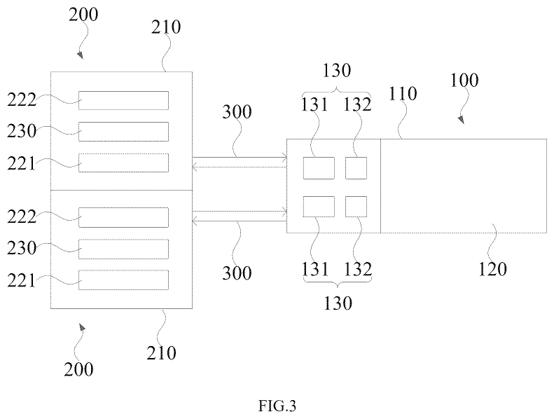

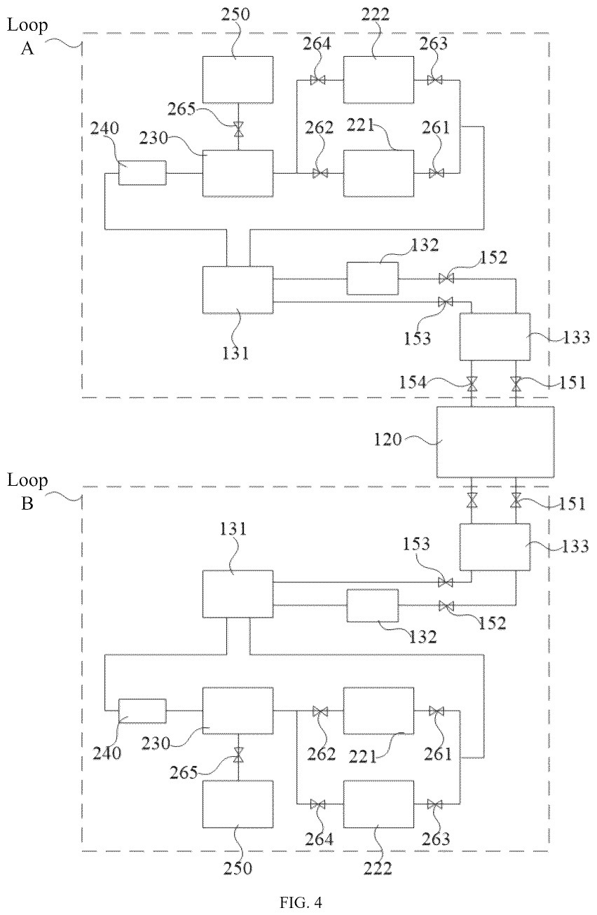

Referring to FIG. 3 and FIG. 4, an embodiment of the present application provides another immersion liquid cooling system. The difference of this immersion liquid cooling system from the immersion liquid cooling system shown in FIG. 1 and FIG. 2 lies in: this immersion liquid cooling system includes a liquid cooling device 100 and two refrigerating devices 200, and the liquid cooling device 100 includes a liquid cooling cabinet 120, two cooling capacity distribution units 130 and two first electronic control apparatuses. The two cooling capacity distribution units 130 are simultaneously connected to the liquid cooling cabinet 120. The two first electronic control apparatuses respectively control the two cooling capacity distribution units 130. The two refrigerating devices 200 respectively exchange heat with heat exchangers 131 of the two cooling capacity distribution units 130. The two first electronic control apparatuses may be communicatively connected, whereby the two first electronic control apparatuses cooperate with each other to control the immersion liquid cooling system.

Thus, it can be seen that in the immersion liquid cooling system of the embodiments of the present application, a liquid cooling cabinet 120 can be equipped with cooling systems of two loops: loop A and loop B. The cooling system of each loop includes a refrigerating device 200, a cooling capacity distribution unit 130, and a first electronic control apparatus. Two inlet-liquid ports and two return-liquid ports can be arranged on the liquid cooling cabinet 120. One inlet-liquid port and one return-liquid port communicate with the cooling system of loop A, while the other inlet-liquid port and the other return-liquid port communicate with the cooling system of loop B. For the connection manner and characteristics inside the cooling system of each loop, as well as the connection manner and characteristics between the cooling system of each loop and the liquid cooling cabinet 120, reference can all be made to the description about the immersion liquid cooling system shown in FIG. 1 and FIG. 2 above.

It should be noted that, the inlet-liquid temperature sensor and the return-liquid temperature sensor provided in the housing 110 may be electronically connected to the first electronic control apparatus of loop A and the first electronic control apparatus of loop B simultaneously. Or, the inlet-liquid temperature sensor and the return-liquid temperature sensor for loop A can be respectively arranged near an inlet-liquid port and an return-liquid port of the liquid cooling cabinet 120 which connect to the cooling system of loop A, and the inlet-liquid temperature sensor and the return-liquid temperature sensor for loop A are electronically connected to the first electronic control apparatus of loop A; the inlet-liquid temperature sensor and the return-liquid temperature sensor for loop B can be respectively arranged near an inlet-liquid port and an return-liquid port of the liquid cooling cabinet 120 which connect to the cooling system of loop B, and the inlet-liquid temperature sensor and the return-liquid temperature sensor of loop B are electronically connected to the first electronic control apparatus of loop B. In this way, the first electronic control apparatuses of loop A and loop B can both acquire an inlet-liquid temperature and a return-liquid temperature of the liquid cooling cabinet 120, and therefore, the immersion liquid cooling system can be controlled better.

The two cooling capacity distribution units 130 can be arranged on a same side of the liquid cooling cabinet 120; or, the two cooling capacity distribution units 130 can be respectively arranged on two opposite sides of the liquid cooling cabinet 120.

The two refrigerating devices 200 can be integrated together. For example, the mounting brackets 210 of the two refrigerating devices 200 can be fixedly connected together, or, the mounting brackets 210 of the two refrigerating devices 200 can be an integral part.

An embodiment of the present application also provides a data center (not shown in the drawings). The data center includes a server room and the immersion liquid cooling system described above. The liquid cooling device of the immersion liquid cooling system may be arranged inside the server room, and the refrigerating device of the immersion liquid cooling system may be arranged outside the server room. For example, the refrigerating device of the immersion liquid cooling system may be arranged on a top surface of the server room. The liquid cooling device and the refrigerating device can be connected via a pipeline 300 passing through a wall of the server room, for example, the pipeline 300 includes, but not limited to, a copper pipeline.

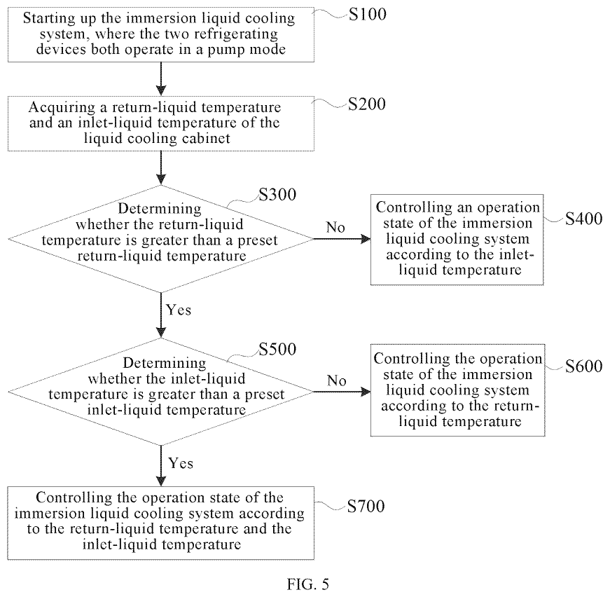

Referring to FIG. 5 to FIG. 10, an embodiment of the present application provides a control method of an immersion liquid cooling system, which is applicable to the immersion liquid cooling system as shown in FIG. 3 and FIG. 4. For example, an executing body for the control method of the immersion liquid cooling system in the embodiment of the present application may be a first electronic control apparatus, and the first electronic control apparatus may be implemented through software or a combination of software and hardware. Or, the executing body for the control method of the immersion liquid cooling system in the embodiment of the present application may be a master controller, and the master controller may be communicatively connected to an electronic control apparatus of the immersion liquid cooling system (the first electronic control apparatus and the second electronic control apparatus), to perform the control method of the immersion liquid cooling system in the immersion liquid cooling system.

Referring to FIG. 5, the control method of the immersion liquid cooling system may include:
S100: starting up the immersion liquid cooling system, where the two refrigerating devices both operate in a pump mode.

The immersion liquid cooling system of the embodiments of the present application includes two cooling systems, i.e., loop A and loop B. In the case that the immersion liquid cooling system is started up normally, loop A and loop B work simultaneously, they share the load equally and each bears 50% of the flow of the immersion liquid cooling system. When one of loop A and loop B fails, the other loop can take over the entire immersion liquid cooling system, so that the immersion liquid cooling system can continue to operate, and the safety and reliability of the immersion liquid cooling system are improved.

After the immersion liquid cooling system is started up normally, the refrigerating devices of loop A and loop B both operate in the pump mode, i.e., the refrigerating circulation pumps of the refrigerating devices of loop A and loop B work, while the compressors do not work. Rotating speeds of the refrigerating circulation pumps of loop A and loop B are initial rotating speeds, for example, an initial speed may be 50%-60% of a rated speed of a refrigerating circulation pump. It should be noted that in the following control methods, steps except those explicitly specified as single-loop control are all aimed at simultaneous control of loop A and loop B.
S200: acquiring a return-liquid temperature and an inlet-liquid temperature of the liquid cooling cabinet.

For example, the return-liquid temperature of the liquid cooling cabinet can be acquired by a return-liquid temperature sensor and transmitted to the first electronic control apparatus or other executing body; the inlet-liquid temperature of the liquid cooling cabinet can be acquired by an inlet-liquid temperature sensor and transmitted to the first electronic control apparatus or other executing body.
S300: determining whether the return-liquid temperature is greater than a preset return-liquid temperature.

The preset return-liquid temperature is a temperature set in advance in the first electronic control apparatus or other executing body according to the actual situation. For example, when a GPU (Graphics Processing Unit, translation: graphics processing unit) server is accommodated in a liquid cooling cabinet, the preset return-liquid temperature can be 37° C., and when a CPU (Central Processing Unit, translation: central processing unit) server is accommodated in the liquid cooling cabinet, the preset return-liquid temperature can be 45° C.

If not, S400: controlling an operation state of the immersion liquid cooling system according to the inlet-liquid temperature.

The operation state of the immersion liquid cooling system includes: the two refrigerating devices both operating in a compressor mode; the two refrigerating devices both operating in the pump mode; or, one of the two refrigerating devices operating in the compressor mode and the other one operating in the pump mode. The refrigerating device operating in the compressor mode means that the compressor of the refrigerating device works and the refrigerating circulation pump stops working; the refrigerating device operating in the pump mode means that the refrigerating circulation pump of the refrigerating device works and the compressor stops working.

Continuing to refer to FIG. 5, after the step of “S300: determining whether the return-liquid temperature is greater than a preset return-liquid temperature”, the method may further include:
if so, S500: determining whether the inlet-liquid temperature is greater than a preset inlet-liquid temperature.

The preset inlet-liquid temperature is a temperature set in advance in the first electronic control apparatus or other executing body according to the actual situation. For example, when the GPU server is accommodated in the liquid cooling cabinet, the preset inlet-liquid temperature can be 30° C., and when the CPU server is accommodated in the liquid cooling cabinet, the preset inlet-liquid temperature can be 38° C.

If not, S600: controlling the operation state of the immersion liquid cooling system according to the return-liquid temperature.

If so, S700: controlling the operation state of the immersion liquid cooling system according to the return-liquid temperature and the inlet-liquid temperature.

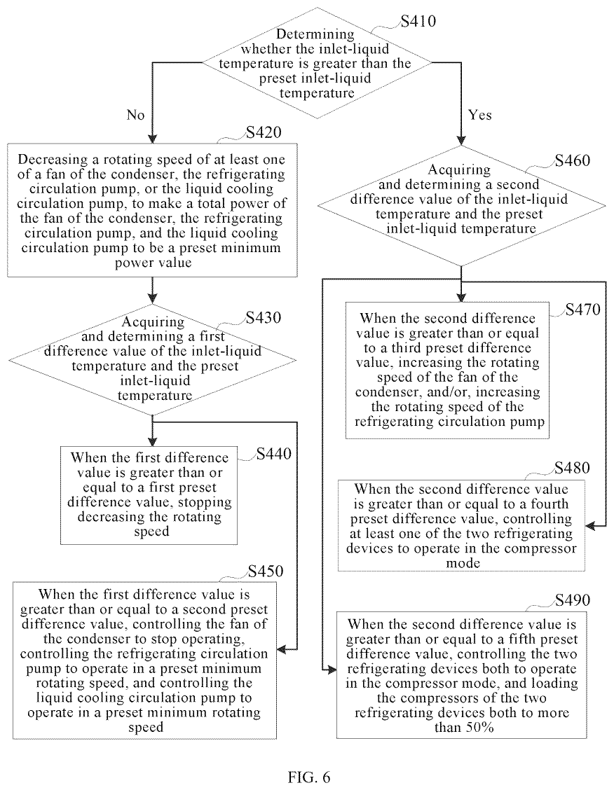

Referring to FIG. 6, the step of “S400: controlling an operation state of the immersion liquid cooling system according to the inlet-liquid temperature” may include:
S410: determining whether the inlet-liquid temperature is greater than the preset inlet-liquid temperature.

If not, S420: decreasing a rotating speed of at least one of a fan of the condenser, the refrigerating circulation pump, or the liquid cooling circulation pump, to make a total power of the fan of the condenser, the refrigerating circulation pump, and the liquid cooling circulation pump to be a preset minimum power value.

For example, the rotating speeds of the fan of the condenser, the refrigerating circulation pump, and the liquid cooling circulation pump can all be decreased with a step of 1%, 2%, 5%, 8% or 10%, etc. of the rated rotating speeds. The preset minimum power value may be a power value set in advance in the first electronic control apparatus or other executing body according to the actual situation. Or, the preset minimum power value may be a power value obtained by the prediction of the first electronic control apparatus or other executing body according to the inlet-liquid temperature, a parameter of the fan of the condenser, a parameter of the refrigerating circulation pump, a parameter of the liquid cooling circulation pump and a prediction model. The prediction model may be trained by the first electronic control apparatus or other executing body by learning the inlet-liquid temperature, the parameter of the fan of the condenser, the parameter of the refrigerating circulation pump, the parameter of the liquid cooling circulation pump, and their corresponding total power over a period of time in the past.
S430: acquiring and determining a first difference value of the inlet-liquid temperature and the preset inlet-liquid temperature.

It can be understood that at this time, the inlet-liquid temperature is smaller than or equal to the preset inlet-liquid temperature, and the first difference value may be obtained by subtracting the inlet-liquid temperature from the preset inlet-liquid temperature.
S440: when the first difference value is greater than or equal to a first preset difference value, stopping decreasing the rotating speed.

For example, the first preset difference value may be 1° C., or, the first preset difference value may be set to other values according to actual needs. The stopping decreasing the rotating speed includes stopping decreasing the rotating speed of the fan of condenser, stopping decreasing the rotating speed of the refrigerating circulation pump, and stopping decreasing the rotating speed of the liquid cooling circulation pump.

It should be understood that, after the rotating speed is stopped to be decreased, if the inlet-liquid temperature does not exceed the preset inlet-liquid temperature, the states of the fan of the condenser, the refrigerating circulation pump and liquid cooling circulation pump can be maintained unchanged; if the inlet-liquid temperature reaches the preset inlet-liquid temperature, the step of increasing the rotating speed of at least one of the fan of the condenser, the refrigerating circulation pump or the liquid cooling circulation pump, or a step of switching to the compressor operation mode in the following text can be performed.
S450: when the first difference value is greater than or equal to a second preset difference value, controlling the fan of the condenser to stop operating, controlling the refrigerating circulation pump to operate in a preset minimum rotating speed, and controlling the liquid cooling circulation pump to operate in a preset minimum rotating speed.

The first preset difference value is smaller than the second preset difference value. For example, the second preset difference value may be 3° C. or 5° C., or, the second preset difference value may be set to other values according to actual needs. The preset minimum rotating speed of the refrigerating circulation pump and the preset minimum rotating speed of the liquid cooling circulation pump may be rotating speed values set in advance in the first electronic control apparatus or other executing body according to actual situation. For example, the preset minimum rotating speed of the refrigerating circulation pump may be 30% of a rated rotating speed of the refrigerating circulation pump, the preset minimum rotating speed of the liquid cooling circulation pump may be 40% of a rated rotating speed of the liquid cooling circulation pump.

It should be understood that, after controlling the fan of the condenser to stop operating, controlling the refrigerating circulation pump to operate in the preset minimum rotating speed, and controlling the liquid cooling circulation pump to operate in the preset minimum rotating speed, if the first difference value is approaching the first preset difference value, the step of increasing the rotating speed of at least one of the fan of the condenser, the refrigerating circulation pump or the liquid cooling circulation pump, or the steps of switching to the compressor operation mode in the following text can be performed.

Referring to FIG. 6, the step of “S400: controlling an operation state of the immersion liquid cooling system according to the inlet-liquid temperature” may include:
S410: determining whether the inlet-liquid temperature is greater than the preset inlet-liquid temperature.
if so, S460: acquiring and determining a second difference value of the inlet-liquid temperature and the preset inlet-liquid temperature.

It can be understood that at this time, the inlet-liquid temperature is greater than the preset inlet-liquid temperature, and the second difference value may be obtained by subtracting the preset inlet-liquid temperature from the inlet-liquid temperature.
S470: when the second difference value is greater than or equal to a third preset difference value, increasing the rotating speed of the fan of the condenser, and/or, increasing the rotating speed of the refrigerating circulation pump.

For example, the rotating speeds of the fan of the condenser and the refrigerating circulation pump can both be increased with a step of 1%, 2%, 5%, 8% or 10%, etc. of the rated rotating speeds.

It should be understood that, if increasing the rotating speed of the fan of the condenser, and/or, increasing the rotating speed of the refrigerating circulation pump can decrease the inlet-liquid temperature to be below the preset inlet-liquid temperature, the step of decreasing the rotating speed of at least one of the fan of the condenser, the refrigerating circulation pump or the liquid cooling circulation pump in the previous text, or the step of maintaining the rotating speeds of the fan of the condenser, the refrigerating circulation pump and the liquid cooling circulation pump unchanged can be performed.
S480: when the second difference value is greater than or equal to a fourth preset difference value, controlling at least one of the two refrigerating devices to operate in the compressor mode.

For example, the second difference value being greater than or equal to the fourth preset difference value includes two situations: first, when the rotating speed of the fan of the condenser and the rotating speed of the refrigerating circulation pump are both increased to the rated speeds, the second difference value still continues to increase to the fourth preset difference value; secondly, a starting value of the second difference value is greater than or equal to the fourth preset difference value. At this time, the refrigerating device of loop A can be controlled to operate in the compressor mode; or, the refrigerating device of loop B can be controlled to operate in the compressor mode; or, the refrigerating devices of loop A and loop B can both be controlled to operate in the compressor mode.
S490: when the second difference value is greater than or equal to a fifth preset difference value, controlling the two refrigerating devices both to operate in the compressor mode, and loading the compressors of the two refrigerating devices both to more than 50%.

For example, the second difference value being greater than or equal to the fifth preset difference value includes two situations: first, when the refrigerating devices of loop A and loop B both operate in the compressor mode, and the compressors of the two refrigerating devices are both loaded to 50%, the second difference value still cannot be decreased to be below the fifth preset difference value; secondly, a starting value of the second difference value is greater than or equal to the fifth preset difference value. At this time, the compressors of the refrigerating devices of loop A and loop B are simultaneously loaded to over 50%.

The third preset difference value, the fourth preset difference value, and the fifth preset difference value increase sequentially. For example, the third preset difference value, the fourth preset difference value, and the fifth preset difference value may be 1° C., 2° C., 3° C., or 2° C., 4° C., 6° C., or 1° C., 3° C., 5° C., etc., sequentially.

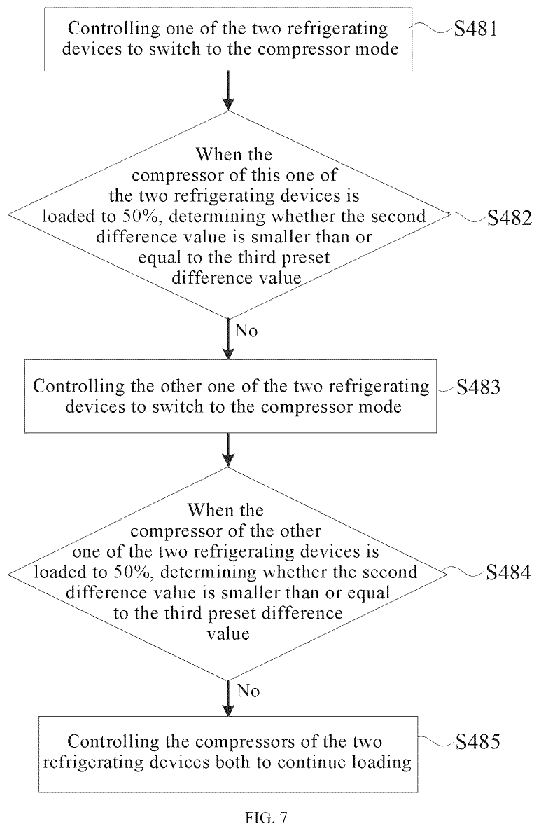

Referring to FIG. 7, the step of “S480: when the second difference value is greater than or equal to a fourth preset difference value, controlling at least one of the two refrigerating devices to operate in the compressor mode” may include:
S481: controlling one of the two refrigerating devices to switch to the compressor mode.

For example, the refrigerating device of loop A may be controlled to switch to the compressor mode; by controlling the fifth regulating valve, the sixth regulating valve, the seventh regulating valve and the eighth regulating valve of the refrigerating device of loop A, the refrigerating device of loop A is switched from the pump mode to the compressor mode.
S482: when the compressor of this one of the two refrigerating devices is loaded to 50%, determining whether the second difference value is smaller than or equal to the third preset difference value.

For example, when the compressor of the refrigerating device of loop A is loaded to 50%, it is determined whether the second difference value is smaller than or equal to the third preset difference value.

If not, S483: controlling the other one of the two refrigerating devices to switch to the compressor mode.

For example, the refrigerating device of loop B may be controlled to switch to the compressor mode; by controlling the fifth regulating valve, the sixth regulating valve, the seventh regulating valve and the eighth regulating valve of the refrigerating device of loop B, the refrigerating device of loop B is switched from the pump mode to the compressor mode.
S484: when the compressor of the other one of the two refrigerating devices is loaded to 50%, determining whether the second difference value is smaller than or equal to the third preset difference value.

For example, when the compressor of the refrigerating device of loop B is loaded to 50%, it is determined whether the second difference value is smaller than or equal to the third preset difference value.

If not, S485: controlling the compressors of the two refrigerating devices both to continue loading.

For example, the compressors of the two refrigeration devices can be loaded with a step of 5% or 10%. Each time of load increase, the second difference value can be verified once. If the second difference value remains stable at 0, operation states of the compressors can be maintained unchanged; if the second difference stabilizes at the fourth preset difference value, loading rates of the compressors can be accelerated; if the second difference value stabilizes below the third preset difference value, the loading rates of the compressors can be slowed down.

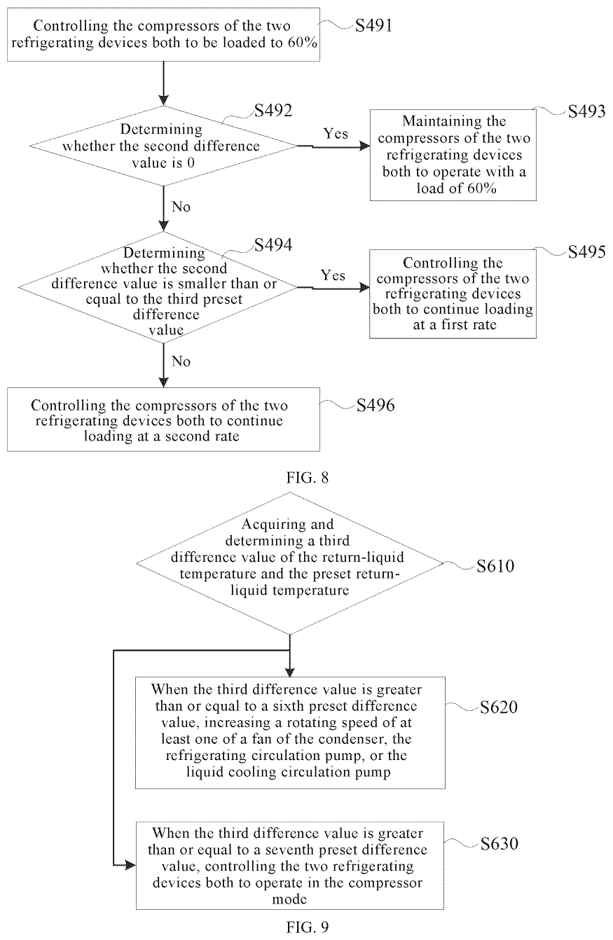

Referring to FIG. 8, the step of “S490: when the second difference value is greater than or equal to a fifth preset difference value, controlling the two refrigerating devices both to operate in the compressor mode, and loading the compressors of the two refrigerating devices both to more than 50%” may include:
S491: controlling the compressors of the two refrigerating devices both to be loaded to 60%.
S492: determining whether the second difference value is 0.

If so, S493: maintaining the compressors of the two refrigerating devices both to operate with a load of 60%.

If not, S494: determining whether the second difference value is smaller than or equal to the third preset difference value.

If so, S495: controlling the compressors of the two refrigerating devices both to continue loading at a first rate.

For example, the compressors of the two refrigeration devices can both be loaded with a step of 5% or 10%.

If not, S496: controlling the compressors of the two refrigerating devices both to continue loading at a second rate.

For example, the compressors of the two refrigeration devices can both be loaded with a step of 5% or 10%.

The first rate is smaller than the second rate. The first rate and the second rate may be rate values set in advance in the first electronic control apparatus or other executing body according to actual situation.

Referring to FIG. 9, the step of “S600: controlling the operation state of the immersion liquid cooling system according to the return-liquid temperature” may include:
S610: acquiring and determining a third difference value of the return-liquid temperature and the preset return-liquid temperature.

At this time, the return-liquid temperature is greater than the preset return-liquid temperature, and the third difference value may be obtained by subtracting the preset return-liquid temperature from the return-liquid temperature.
S620: when the third difference value is greater than or equal to a sixth preset difference value, increasing a rotating speed of at least one of a fan of the condenser, the refrigerating circulation pump, or the liquid cooling circulation pump.

For example, the rotating speeds of the fan of the condenser, the refrigerating circulation pump, and the liquid cooling circulation pump can all be increased with a step of 1%, 2%, 5%, 8% or 10%, etc. of the rated rotating speeds.
S630: when the third difference value is greater than or equal to a seventh preset difference value, controlling the two refrigerating devices both to operate in the compressor mode.

The sixth preset difference value is smaller than the seventh preset difference value. For example, the sixth preset difference value and the seventh preset difference value may be 1° C., 2° C., or 2° C., 4° C., or 1° C., 3° C., etc., sequentially.

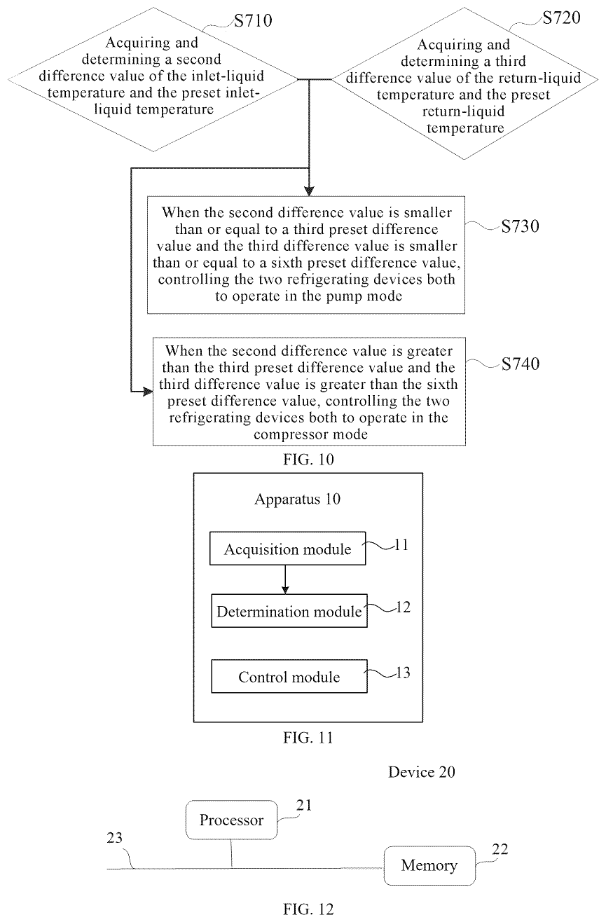

Referring to FIG. 10, the step of “S700: controlling the operation state of the immersion liquid cooling system according to the return-liquid temperature and the inlet-liquid temperature” may include:
S710: acquiring and determining a second difference value of the inlet-liquid temperature and the preset inlet-liquid temperature.
S720: acquiring and determining a third difference value of the return-liquid temperature and the preset return-liquid temperature.
S730: when the second difference value is smaller than or equal to a third preset difference value and the third difference value is smaller than or equal to a sixth preset difference value, controlling the two refrigerating devices both to operate in the pump mode.
S740: when the second difference value is greater than the third preset difference value and the third difference value is greater than the sixth preset difference value, controlling the two refrigerating devices both to operate in the compressor mode.

In a possible implementation, the control method of an immersion liquid cooling system of an embodiment of the present application further includes:
acquiring a condensing temperature of the condenser.

For example, a condensing temperature sensor may be installed on the condenser, and the condensing temperature sensor can collect the condensing temperature. The condensing temperature sensor can directly transmit the condensing temperature to the first electronic control apparatus or other executing body, or the condensation temperature sensor can also transmit the condensing temperature to the first electronic control apparatus or other executing body through the second electronic control apparatus.

When the condensing temperature is greater than a preset condensing temperature, a spraying apparatus is controlled to spray coolant to the condenser.

The preset condensing temperature may be a temperature set in advance in the first electronic control apparatus or other executing body according to actual situation. For example, the preset condensing temperature may be set to 45° C. or other temperature values according to actual needs.

When the condensing temperature is smaller than the preset condensing temperature, and a difference value of the condensing temperature and the preset condensing temperature is greater than or equal to an eighth preset difference value, the spraying apparatus is controlled to stop spraying.

For example, the eighth preset difference value may be 3° C., or, the eighth preset difference value may be set to other values according to actual needs.

In a possible implementation, the control method of an immersion liquid cooling system of an embodiment of the present application further includes:
acquiring an outdoor environment temperature, and a difference value of an outdoor dry bulb temperature and an outdoor wet bulb temperature.

For example, the outdoor environment temperature may be acquired through an outdoor environment temperature sensor, the dry bulb temperature may be acquired through a dry bulb temperature sensor, and the wet bulb temperature may be acquired through a wet bulb temperature sensor. The outdoor environment temperature sensor, the dry bulb temperature sensor, and the wet bulb temperature sensor may be arranged on the refrigerating device(s), or on other outdoor positions. The outdoor environment temperature sensor, the dry bulb temperature sensor, and the wet bulb temperature sensor may directly transmit the acquired temperatures to the first electronic control apparatus or other executing body; or, the outdoor environment temperature sensor, the dry bulb temperature sensor, and the wet bulb temperature sensor may also transmit the acquired temperatures to the first electronic control apparatus or other executing body through the second electronic control apparatus.

When the outdoor environment temperature is greater than a preset temperature, and the difference value of the outdoor dry bulb temperature and the outdoor wet bulb temperature is greater than a ninth preset difference value, the spraying apparatus is controlled to spray coolant to the condenser.

When the outdoor environment temperature is smaller than the preset temperature, the spraying apparatus is controlled to stop spraying.

For example, the preset temperature is a temperature set in advance in the first electronic control apparatus or other executing body according to actual situation. For example, the preset temperature may be set to 25° C., 30° C., or other temperature values according to actual needs. The ninth preset difference value may be 6° C., or, the ninth preset difference value may be set to other values according to actual needs.

A GPU server or a CPU server may be accommodated in the liquid cooling cabinet of the immersion liquid cooling system provided in the embodiments of the present application. When the GPU server is accommodated in the liquid cooling cabinet of the immersion liquid cooling system, for the operating temperatures and operation states of the immersion liquid cooling system, reference can be made to a table 1 below. When the CPU server is accommodated in the liquid cooling cabinet of the immersion liquid cooling system, for the operating temperatures and operation states of the immersion liquid cooling system, reference can be made to a table 2 below.

TABLE 1

| | | | | Applicable outdoor |
|---|---|---|---|---|
| | | | Control | environmental |
| No. | | Content | target | temperature range |
| 1 | High | Maximum inlet- | 33° C. | 30° C. to 45° C. |
| | temper- | liquid temperature | | |
| 2 | ature | Maximum return- | 40° C. | 30° C. to 45° C. |
| | interval | liquid temperature | | |
| 3 | | Difference between | 7° C. | 30° C. to 45° C. |
| | | the inlet-liquid and | | |
| | | return-liquid | | |
| | | temperatures | | |
| 4 | | Operation | | During the high |
| | | description | | temperature interval, |
| | | | | a primary target is to |
| | | | | ensure the inlet-liquid |
| | | | | temperature, |
| | | | | followed by |
| | | | | considerations |
| | | | | of power |
| | | | | saving. During this |
| | | | | interval, the |
| | | | | compressor |
| | | | | needs to be turned |
| | | | | on for most cases. |
| 5 | Normal | Maximum inlet- | 30° C. | −35° C. to 30° C. |
| | interval | liquid temperature | | |
| 6 | | Maximum return- | 37° C. | −35° C. to 30° C. |
| | | liquid temperature | | |
| 7 | | Difference between | 12-14° C. | −35° C. to 30° C., |
| | | the inlet-liquid and | | seeking a lowest |
| | | return-liquid | | power consumption |
| | | temperatures | | |
| 8 | | Operation | | During this interval, to |
| | | description | | ensure power saving: it |
| | | | | is allowed to switch the |
| | | | | interval temperature to |
| | | | | exceed 30° C. |
| | | | | for a short |
| | | | | period of time, but not |
| | | | | exceeding 33° C.; |
| | | | | the return-liquid is |
| | | | | allowed to exceed |
| | | | | 37° C. for a short |
| | | | | period of time; |
| | | | | and the temperature |
| | | | | difference can |
| | | | | be increased, but |
| | | | | the maximum return- |
| | | | | liquid temperature |
| | | | | cannot exceed 40° C. |
| | | | | The unit needs to |
| | | | | operate optimally |
| | | | | in the mode with |
| | | | | a lowest total |
| | | | | power of the |
| | | | | liquid cooling |
| | | | | circulation pump, the |
| | | | | refrigerating |
| | | | | circulation |
| | | | | pump (compressor), |
| | | | | and the fan of |
| | | | | the condenser. |
| 9 | Spraying | Optional | | Turning on when an |
| | mode | | | environmental |
| | | | | temperature exceeds |
| | | | | 25 degrees, it is |
| | | | | estimated that the |
| | | | | environmental |
| | | | | temperature |
| | | | | can be decreased by 6 |
| | | | | degrees. |

TABLE 2

| | | | | Applicable outdoor |
|---|---|---|---|---|
| | | | Control | environmental |
| No. | | Content | target | temperature range |
| 1 | High | Maximum inlet- | 41° C. | 30° C. to 45° C. |
| | temper- | liquid temperature | | |
| 2 | ature | Maximum return- | 48° C. | 30° C. to 45° C. |
| | interval | liquid temperature | | |
| 3 | | Difference between | 7° C. | 30° C. to 45° C. |
| | | the inlet-liquid and | | |
| | | return-liquid | | |
| | | temperatures | | |
| 4 | | Operation | | During the high |
| | | description | | temperature interval, |
| | | | | a primary target is to |
| | | | | ensure the inlet-liquid |
| | | | | temperature, |
| | | | | followed by |
| | | | | considerations of |
| | | | | power saving. |
| 5 | Normal | Maximum inlet- | 38° C. | −35° C. to 30° C. |
| | interval | liquid temperature | | |
| 6 | | Maximum return- | 45° C. | −35° C. to 30° C. |
| | | liquid temperature | | |
| 7 | | Difference between | 12-14° C. | −35° C. to 30° C., |
| | | the inlet-liquid and | | seeking a lowest |
| | | return-liquid | | power consumption |
| | | temperatures | | |
| 8 | | Operation | | During this interval, to |
| | | description | | ensure power saving: it |
| | | | | is allowed to switch the |
| | | | | interval temperature to |
| | | | | exceed 38° C. |
| | | | | for a short period |
| | | | | of time, but not |
| | | | | exceeding 41° C.; |
| | | | | the return-liquid is |
| | | | | allowed to exceed |
| | | | | 45° C. for a short |
| | | | | period of time; |
| | | | | and the temperature |
| | | | | difference can |
| | | | | be increased, but |
| | | | | the maximum return- |
| | | | | liquid temperature |
| | | | | cannot exceed 48° C. |
| | | | | The unit needs to |
| | | | | operate optimally |
| | | | | in the mode with |
| | | | | a lowest total |
| | | | | power of the |
| | | | | liquid cooling |
| | | | | circulation pump, the |
| | | | | refrigerating |
| | | | | circulation |
| | | | | pump (compressor), |
| | | | | and the fan of the |
| | | | | condenser. |
| 9 | Spraying | Optional | | Turning on when an |
| | mode | | | environmental |
| | | | | temperature exceeds |
| | | | | 30° C., it is estimated |
| | | | | that the environmental |
| | | | | temperature can be |
| | | | | decreased by 6° C. |

Referring to FIG. 11, an embodiment of the present application provides a control apparatus 10 of an immersion liquid cooling system. The control apparatus 10 includes: an acquisition module 11, a determination module 12 and a control module 13.

The acquisition module 11 can be configured to acquire a return-liquid temperature and an inlet-liquid temperature of the liquid cooling cabinet.

The determination module 12 can be configured to determine whether the return-liquid temperature is greater than a preset return-liquid temperature; and can be configured to determine whether the inlet-liquid temperature is greater than a preset inlet-liquid temperature.

The control module 13 can be configured to start up the immersion liquid cooling system, to make the two refrigerating devices both operate in a pump mode; can be configured to control an operation state of the immersion liquid cooling system according to the inlet-liquid temperature; can be configured to control an operation state of the immersion liquid cooling system according to the return-liquid temperature; and can be configured to control the operation state of the immersion liquid cooling system according to the return-liquid temperature and the inlet-liquid temperature.

The acquisition module 11, the determination module 12 and the control module 13 are connected in sequence. The control apparatus 10 of an immersion liquid cooling system provided in the embodiment of the present application can execute the control method of the immersion liquid cooling system mentioned above, for its operation process, reference can be made to the description about the control method of the immersion liquid cooling system in the previous text, which will not be repeated here.

Referring to FIG. 12, an embodiment of the present application provides a control device 20 of an immersion liquid cooling system. The control device 20 includes a processor 21 and a memory 22, where the processor 21 and the memory 22 may be communicatively connected through a communication bus 23. The memory 22 stores computer executable instructions; the processor 21 executes the computer executable instructions stored in the memory 22 to implement the control method of the immersion liquid cooling system mentioned above.

In an implementation, the control device 20 may also include a communication interface, and the communication interface may include a transmitter and/or a receiver.

In an implementation, the processor mentioned above may be a central processing unit (Central Processing Unit, CPU), as well as other general-purpose processors, digital signal processor (Digital Signal Processor, DSP), Application Specific Integrated Circuit (ASIC), etc. A general-purpose processor may be a microprocessor or any conventional processor. The steps of the method disclosed in conjunction with the embodiments of the present application can be directly embodied as being executed by a hardware processor, or executed by a combination of hardware and software modules in the processor.

An embodiment of the present application also provides a computer readable storage medium, where the computer readable storage medium stores computer executable instructions; when the computer executable instructions are executed by a processor, the control method of the immersion liquid cooling system mentioned above is implemented.

An embodiment of the present application provides a program product, including a computer program; when the computer program is executed by a processor, the control method of the immersion liquid cooling system mentioned above is implemented.

In several embodiments provided in the present application, it should be understood that the disclosed apparatuses and methods can be implemented in other ways. For example, the apparatus embodiments described above are only illustrative. For example, the division of units is only a logical functional division. In practical implementation, there may be other division methods, e.g. multiple units or components may be combined or integrated into another system, or some features may be ignored or not executed. On the other hand, the displayed or discussed mutual coupling or direct coupling or communicative connection can be indirect coupling or communicative connection between apparatuses or units through some interface, which can be electrical, mechanical or in other forms.

The units described as separate components may or may not be physically separated, and the components displayed as units may or may not be physical units, i.e. they can be located in one place or distributed across multiple network units. Some or all of the units can be selected according to actual needs to achieve the purpose of the solutions of the embodiments. In addition, respective functional units in various embodiments of the present application can be integrated into a processing unit or physically exist separately, or two or more units can be integrated into one unit. The integrated units mentioned above may be implemented in the form of hardware or in the form of hardware and software functional units.

The integrated units implemented in the form of software functional units mentioned above can be stored in a computer-readable storage medium. The software functional units mentioned above are stored in a storage medium, including several instructions for causing a computer device (which can be a personal computer, a server, or a network device, etc.) or a processor to perform some steps of the methods described in various embodiments of the present application. The storage medium described above includes various media that can store program code(s), such as a USB flash drive, a portable hard drive, a read only memory (Read Only Memory, ROM), a random access memory (Random Access Memory, RAM), a magnetic disk, or an optical disk.

It should be noted that the terms “comprise,” “include,” or any other variants thereof, are intended to cover non-exclusive inclusions, such that a process, method, product, or device that includes a series of elements includes not only those elements, but also other elements not explicitly listed or inherent to such process, method, product, or device. In the absence of more limitations, the elements defined by the phrase “comprising a . . . ” do not exclude the presence of additional identical element(s) in the process, method, product, or device that includes the said element.

Finally, it should be noted that the various embodiments mentioned above are only used to illustrate the technical solution(s) of the present application, and not to limit it. Although the present application has been described in detail with reference to the aforementioned embodiments, those skilled in the art should understand that they can still modify the technical solution(s) described in the aforementioned embodiments, or equivalently replace some or all of the technical features therein. And these modifications or substitutions do not cause the essence of the corresponding technical solution(s) to deviate from the scope of the technical solutions of the various embodiments of the present application.

1. An immersion liquid cooling system, comprising: a liquid cooling device and a refrigerating device, wherein the liquid cooling device and the refrigerating device exchange heat through a heat exchanger;
the liquid cooling device comprises a liquid cooling cabinet and a cooling capacity distribution unit; wherein the cooling capacity distribution unit comprises the heat exchanger and a liquid cooling circulation pump, a first medium outlet of the heat exchanger communicates with an inlet-liquid port of the liquid cooling cabinet, a first medium inlet of the heat exchanger communicates with a return-liquid port of the liquid cooling cabinet, the liquid cooling circulation pump is connected in series between the heat exchanger and the liquid cooling cabinet;
the refrigerating device comprises a refrigerating circulation pump, a condenser, and a throttling apparatus that are sequentially connected in series between a second medium outlet and a second medium inlet of the heat exchanger, and a compressor connected in parallel with the refrigerating circulation pump, wherein one of the compressor and the refrigerating circulation pump is selected to operate.

2. The immersion liquid cooling system according to claim 1, wherein the liquid cooling device further comprises a housing and an electronic control apparatus; the liquid cooling cabinet, the cooling capacity distribution unit, and the electronic control apparatus are all arranged in the housing; the electronic control apparatus is configured to control the cooling capacity distribution unit.

3. The immersion liquid cooling system according to claim 2, wherein an inlet-liquid temperature sensor and a return-liquid temperature sensor are provided in the housing, the inlet-liquid temperature sensor is arranged close to the inlet-liquid port of the liquid cooling cabinet, and the return-liquid temperature sensor is arranged close to the return-liquid port of the liquid cooling cabinet;
the inlet-liquid temperature sensor and the return-liquid temperature sensor are both electrically connected to the electronic control apparatus.

4. The immersion liquid cooling system according to claim 2, wherein a surface of the housing is provided with a touch screen, and the touch screen is configured to control and display a state of the liquid cooling device.

5. The immersion liquid cooling system according to claim 1, wherein the refrigerating device further comprises a spraying apparatus, the spraying apparatus is arranged close to the condenser, and the spraying apparatus is configured to spray coolant to the condenser.

6. The immersion liquid cooling system according to claim 1, wherein the liquid cooling device comprises a first medium, the first medium flows in circulation in the liquid cooling cabinet and the cooling capacity distribution unit, and the first medium is electronic fluorine liquid;
and/or,
the refrigerating device comprises a second medium, the second medium flows in circulation in the heat exchanger and the refrigerating device, and the second medium is Freon.

7. The immersion liquid cooling system according to claim 1, wherein the condenser comprises a condensing tube, a heat dissipation fin, and a fan; the heat dissipation fin is arranged on an outer surface of the condensing tube, the fan is arranged close to the condensing tube, and the fan is configured to drive air around the condensing tube to flow.

8. An immersion liquid cooling system, comprising: a liquid cooling device and two refrigerating devices, wherein the liquid cooling device and the two refrigerating devices exchange heat through a heat exchanger;
the liquid cooling device comprises a liquid cooling cabinet and two cooling capacity distribution units; wherein the cooling capacity distribution unit comprises the heat exchanger and a liquid cooling circulation pump, a first medium outlet of the heat exchanger communicates with an inlet-liquid port of the liquid cooling cabinet, a first medium inlet of the heat exchanger communicates with a return-liquid port of the liquid cooling cabinet, the liquid cooling circulation pump is connected in series between the heat exchanger and the liquid cooling cabinet;
the two refrigerating devices respectively correspond to the two cooling capacity distribution units; the refrigerating device comprises a refrigerating circulation pump, a condenser, and a throttling apparatus that are sequentially connected in series between a second medium outlet and a second medium inlet of the heat exchanger, and a compressor connected in parallel with the refrigerating circulation pump, wherein one of the compressor and the refrigerating circulation pump is selected to operate.

9. The immersion liquid cooling system according to claim 8, wherein the liquid cooling device further comprises a housing and two electronic control apparatuses; the liquid cooling cabinet, the two cooling capacity distribution units, and the two electronic control apparatuses are all arranged in the housing; the two electronic control apparatuses are respectively configured to control the two cooling capacity distribution units.

10. The immersion liquid cooling system according to claim 9, wherein an inlet-liquid temperature sensor and a return-liquid temperature sensor are further provided in the housing, the inlet-liquid temperature sensor is arranged close to the inlet-liquid port of the liquid cooling cabinet, and the return-liquid temperature sensor is arranged close to the return-liquid port of the liquid cooling cabinet;
the inlet-liquid temperature sensor and the return-liquid temperature sensor are both electrically connected to the electronic control apparatus.

11. The immersion liquid cooling system according to claim 9, wherein a surface of the housing is provided with a touch screen, and the touch screen is configured to control and display a state of the liquid cooling device.

12. The immersion liquid cooling system according to claim 8, wherein the refrigerating device further comprises a spraying apparatus, the spraying apparatus is arranged close to the condenser, and the spraying apparatus is configured to spray coolant to the condenser.

13. The immersion liquid cooling system according to claim 8, wherein the liquid cooling device comprises a first medium, the first medium flows in circulation in the liquid cooling cabinet and the cooling capacity distribution unit, and the first medium is electronic fluorine liquid;
and/or,
the refrigerating device comprises a second medium, the second medium flows in circulation in the heat exchanger and the refrigerating device, and the second medium is Freon.

14. The immersion liquid cooling system according to claim 8, wherein the condenser comprises a condensing tube, a heat dissipation fin, and a fan; the heat dissipation fin is arranged on an outer surface of the condensing tube, the fan is arranged close to the condensing tube, and the fan is configured to drive air around the condensing tube to flow.

15. The immersion liquid cooling system according to claim 8, wherein the two cooling capacity distribution units are arranged on a same side of the liquid cooling cabinet;
or, the two cooling capacity distribution units are arranged respectively on two opposite sides of the liquid cooling cabinet;
wherein the two refrigerating devices are integrated together.

16. (canceled)

17. A data center, comprising a server room and an immersion liquid cooling system; wherein the immersion liquid cooling system comprises: a liquid cooling device and a refrigerating device, the liquid cooling device and the refrigerating device exchange heat through a heat exchanger;
the liquid cooling device comprises a liquid cooling cabinet and a cooling capacity distribution unit; wherein the cooling capacity distribution unit comprises the heat exchanger and a liquid cooling circulation pump, a first medium outlet of the heat exchanger communicates with an inlet-liquid port of the liquid cooling cabinet, a first medium inlet of the heat exchanger communicates with a return-liquid port of the liquid cooling cabinet, the liquid cooling circulation pump is connected in series between the heat exchanger and the liquid cooling cabinet;
the refrigerating device comprises a refrigerating circulation pump, a condenser, and a throttling apparatus that are sequentially connected in series between a second medium outlet and a second medium inlet of the heat exchanger, and a compressor connected in parallel with the refrigerating circulation pump, wherein one of the compressor and the refrigerating circulation pump is selected to operate;
wherein the liquid cooling device of the immersion liquid cooling system is arranged inside the server room, the refrigerating device of the immersion liquid cooling system is arranged outside the server room, the liquid cooling device and the refrigerating device are connected via a pipeline passing through a wall of the server room.

18. A control method of an immersion liquid cooling system, applied to the immersion liquid cooling system according to claim 8; wherein the method comprises:
starting up the immersion liquid cooling system, wherein the two refrigerating devices both operate in a pump mode;
acquiring a return-liquid temperature and an inlet-liquid temperature of the liquid cooling cabinet;
determining whether the return-liquid temperature is greater than a preset return-liquid temperature;
if not, controlling an operation state of the immersion liquid cooling system according to the inlet-liquid temperature;
wherein the operation state of the immersion liquid cooling system comprises: the two refrigerating devices both operating in a compressor mode; the two refrigerating devices both operating in the pump mode; or, one of the two refrigerating devices operating in the compressor mode and the other one of the two refrigerating devices operating in the pump mode.

19. (canceled)

20. (canceled)

21. (canceled)

22. (canceled)

23. (canceled)

24. (canceled)

25. (canceled)

26. (canceled)

27. (canceled)

28. A control device, comprising: a processor and a memory;
wherein the memory stores computer executable instructions;
the processor executes the computer executable instructions stored in the memory to implement the control method of the immersion liquid cooling system according to claim 18.

29. A computer readable storage medium, wherein the computer readable storage medium stores computer executable instructions; when the computer executable instructions are executed by a processor, the control method of the immersion liquid cooling system according to claim 18 is implemented.

30. (canceled)

31. A data center, comprising a server room and the immersion liquid cooling system according to claim 8; wherein the liquid cooling device of the immersion liquid cooling system is arranged inside the server room, the refrigerating device of the immersion liquid cooling system is arranged outside the server room, the liquid cooling device and the refrigerating device are connected via a pipeline passing through a wall of the server room.
